(19) United States
(12) Patent Application Publication
(10) Pub. No.: US 2026/0344096 A1
(43) Pub. Date: Oct. 29, 2026

(54) PHOTODIODE ARRAY STRUCTURE AND MANUFACTURING METHOD THEREOF

(71) Applicant: Taiwan-Asia Semiconductor Corporation, Hsinchu City (TW)

(72) Inventor: Ching-Pu Tai, Hsinchu City (TW)

(21) Appl. No.: 19/306,768

(22) Filed: Aug. 21, 2025

(30) Foreign Application Priority Data
Apr. 29, 2025 (TW) 114116199

(51) Int. Cl. H10F 39/00

(52) U.S. Cl. CPC H10F 39/811; H10F 39/8067

(57) ABSTRACT

A photodiode array structure and a manufacturing method thereof are provided. The photodiode array structure comprises a plurality of photodiodes, each including a light-collecting area, a first conductivity type metal ring, and a second conductivity type metal ring. Each first conductivity type metal ring is disposed above each light-collecting area, and each second conductivity type metal ring is disposed outside each light-collecting area. The second conductivity type metal rings of adjacent photodiodes are closely positioned to each other and electrically connected in series to form a common anode.

### CROSS-REFERENCES TO RELATED APPLICATIONS

This application claims the benefit of priority to Taiwanese Patent Application No. 114116199 filed on Apr. 29, 2025, which is hereby incorporated by reference in its entirety.

### BACKGROUND OF THE INVENTION

### Field of the Invention

The present invention relates to a photodiode array structure and a manufacturing method thereof, and more particularly to a photodiode array structure with a common electrode and a manufacturing method thereof.

### Descriptions of the Related Art

A photodiode is an electronic component that converts external light signals into electrical signals. Its core function is to absorb external light for enabling the detection of optical signals and their conversion into measurable current. This conversion is critical for various applications, such as optical communication, optical measurement, and imaging generation.

The mechanism by which a photodiode absorbs external light involves the use of semiconductor materials (e.g., silicon substrates) within the diode. When photons enter the photodiode and are absorbed, their energy excites electrons from the valence band to the conduction band, generating electron-hole pairs. These photogenerated carriers are separated by the built-in electric field within the diode for producing a current.

However, traditional photodiodes face two primary challenges. First, to improve light response efficiency in conventional single-chip photodiodes, a common approach is to enlarge the chip size and increase the light-collecting area. However, increasing the chip size also increases the junction capacitance (Cj), which slows down the charge-discharge speed of the photodiode, making it unsuitable for applications requiring high-frequency switching, such as in optical communications. To address these issues, there is an urgent need in the industry for an innovative photodiode architecture that enhances photoelectric efficiency without increasing junction capacitance, thereby maintaining the chip's response speed.

### SUMMARY OF THE INVENTION

One of the primary objectives of the present invention is to provide an innovative photodiode array structure and a manufacturing method thereof. Compared to traditional photodiodes, the photodiode array structure of the present invention employs wafer transfer and bonding techniques to transfer the epitaxial structure of the photodiode from a fragile epitaxial growth substrate to a high-strength transparent substrate. This enhances the structural integrity of the chip, improves manufacturing yield, reduces production costs, and meets the requirements for cost-effective production. In particular, the present invention utilizes laser sintering technology to form laser-sintered sidewalls within the device structure, effectively blocking external light interference from the device sidewalls, thereby suppressing noise and improving the signal-to-noise ratio (SNR) and photocurrent gain of the device.

Another primary objective of the present invention is to provide an innovative photodiode array structure and a manufacturing method thereof. Unlike conventional photodiode array structures formed by connecting multiple individual dies in series, the photodiode array structure of the present invention achieves the series connection of multiple photodiode dies through a shared anode configuration. This array structure not only offers higher integration but also reduces the need for electrode pads on individual dies, thereby increasing the light-collecting area of each photodiode and improving its light response efficiency. At the same time, it maintains the independent operation characteristics of each die, avoiding a multiplicative increase in junction capacitance that would affect the response speed of the photodiode dies.

To achieve the above objectives, the present invention provides a photodiode array structure comprising a plurality of photodiodes. Each photodiode includes a transparent substrate, a mesa epitaxial layer, a second conductivity type epitaxial layer, a first conductivity type metal ring, and a second conductivity type metal ring. The mesa epitaxial layer includes an intrinsic epitaxial layer, a first conductivity type in-situ doped epitaxial layer, and a laser-sintered sidewall. The first conductivity type in-situ doped epitaxial layer is disposed on the intrinsic epitaxial layer, and the laser-sintered sidewall is disposed at an outer peripheral edge of the first conductivity type in-situ doped epitaxial layer to substantially define a light-collecting area for each photodiode. The second conductivity type epitaxial layer is disposed on the transparent substrate, and the mesa epitaxial layer is disposed on the second conductivity type epitaxial layer. The first conductivity type metal ring is disposed on the surface of the first conductivity type in-situ doped epitaxial layer inside the laser-sintered sidewall, and the second conductivity type metal ring is disposed adjacent to the sidewall of the mesa epitaxial layer and electrically connected to the second conductivity type epitaxial layer. The second conductivity type metal rings of adjacent photodiodes are closely positioned to each other and electrically connected in series to form a common anode.

In one embodiment of the photodiode array structure of the present invention, each first conductivity type in-situ doped epitaxial layer is an N-type in-situ doped indium phosphide (InP) epitaxial layer, with a dopant selected from sulfur (S) or silicon (Si), and a doping concentration of 10¹⁷ to 10¹⁹ cm⁻³.

In one embodiment of the photodiode array structure of the present invention, each photodiode further includes an optical bonding layer interposed between the transparent substrate and the second conductivity type epitaxial layer to block external light from entering the second conductivity type epitaxial layer through the transparent substrate.

In one embodiment of the photodiode array structure of the present invention, each optical bonding layer is a distributed Bragg reflector (DBR) layer.

In one embodiment of the photodiode array structure of the present invention, each photodiode further includes an optical filtering layer, which is a multi-channel band-pass filter (MBPF) layer covering the surface and sidewalls of the mesa epitaxial layer, allowing light of a specific wavelength band from external light to pass while blocking other wavelengths from entering the light-collecting area.

In one embodiment of the photodiode array structure of the present invention, each optical filtering layer further includes an anti-reflection (AR) layer to reduce surface reflection loss of the optical filtering layer.

To achieve the above objectives, the present invention provides a photodiode array structure comprising a plurality of photodiodes. Each photodiode includes a light-collecting area, a first conductivity type metal ring, and a second conductivity type metal ring. Each first conductivity type metal ring is disposed above each light-collecting area, and each second conductivity type metal ring is disposed outside each light-collecting area. The second conductivity type metal rings of adjacent photodiodes are closely positioned to each other and electrically connected in series to form a common anode.

In another embodiment of the photodiode array structure of the present invention, each photodiode further includes a mesa epitaxial layer having an intrinsic epitaxial layer, a first conductivity type in-situ doped epitaxial layer, and a laser-sintered sidewall. Each first conductivity type in-situ doped epitaxial layer is disposed on each intrinsic epitaxial layer, and each laser-sintered sidewall is disposed at an outer peripheral edge of each first conductivity type in-situ doped epitaxial layer to substantially define the light-collecting area of each photodiode.

In another embodiment of the photodiode array structure of the present invention, each photodiode further includes a second conductivity type epitaxial layer, with each mesa epitaxial layer disposed on each second conductivity type epitaxial layer. Each first conductivity type metal ring is electrically connected to each first conductivity type in-situ doped epitaxial layer, and each second conductivity type metal ring is electrically connected to each second conductivity type epitaxial layer.

In another embodiment of the photodiode array structure of the present invention, each photodiode further includes an optical bonding layer and a transparent substrate, with each optical bonding layer interposed between each transparent substrate and each second conductivity type epitaxial layer to block external light from entering the second conductivity type epitaxial layer through the transparent substrate.

In another embodiment of the photodiode array structure of the present invention, each optical bonding layer is a distributed Bragg reflector (DBR) layer.

In another embodiment of the photodiode array structure of the present invention, each photodiode further includes an optical filtering layer, which is a multi-channel band-pass filter (MBPF) layer covering the surface and sidewalls of the mesa epitaxial layer, allowing light of a specific wavelength band from external light to pass while blocking other wavelengths from entering the light-collecting area.

In another embodiment of the photodiode array structure of the present invention, each optical filtering layer further includes an anti-reflection (AR) layer to reduce surface reflection loss of the optical filtering layer.

To achieve the above objectives, the present invention provides a method for manufacturing a photodiode array structure, comprising the steps of: providing a transparent substrate having a plurality of mesa epitaxial layers thereon; and dicing the transparent substrate to form a plurality of photodiodes, each photodiode including one of the mesa epitaxial layers, a first conductivity type metal ring, and a second conductivity type metal ring, wherein each first conductivity type metal ring is disposed above each mesa epitaxial layer, and each second conductivity type metal ring is disposed outside each mesa epitaxial layer, wherein the second conductivity type metal rings of adjacent photodiodes are closely disposed to each other and electrically connected in series to form a common anode.

In one embodiment of the method for manufacturing the photodiode array structure of the present invention, each mesa epitaxial layer includes an intrinsic epitaxial layer, a first conductivity type in-situ doped epitaxial layer, and a laser-sintered sidewall, wherein each first conductivity type in-situ doped epitaxial layer is disposed on each intrinsic epitaxial layer, and each laser-sintered sidewall is disposed at an outer peripheral edge of each first conductivity type in-situ doped epitaxial layer to substantially define a light-collecting area for each photodiode.

In one embodiment of the method for manufacturing the photodiode array structure of the present invention, each photodiode further includes a second conductivity type epitaxial layer, with each mesa epitaxial layer disposed on each second conductivity type epitaxial layer, each first conductivity type metal ring electrically connected to each first conductivity type in-situ doped epitaxial layer, and each second conductivity type metal ring electrically connected to each second conductivity type epitaxial layer.

In one embodiment of the method for manufacturing the photodiode array structure of the present invention, each photodiode further includes an optical bonding layer and a transparent substrate, with each optical bonding layer interposed between each transparent substrate and each second conductivity type epitaxial layer to block external light from entering the second conductivity type epitaxial layer through the transparent substrate.

In one embodiment of the method for manufacturing the photodiode array structure of the present invention, each photodiode further includes an optical filtering layer, which is a multi-channel band-pass filter (MBPF) layer covering the surface and sidewalls of the mesa epitaxial layer, allowing light of a specific wavelength band from external light to pass while blocking other wavelengths from entering the light-collecting area.

In one embodiment of the method for manufacturing the photodiode array structure of the present invention, each optical filtering layer further includes an anti-reflection (AR) layer to reduce surface reflection loss of the optical filtering layer.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 to FIG. 9 are cross-sectional schematic diagrams illustrating the manufacturing of a photodiode array structure in one embodiment of the present invention;

FIG. 10 is a schematic diagram comparing a photodiode array structure employing the present invention with one not employing the present invention in one embodiment;

FIG. 11 is a schematic diagram of a packaged chip including two photodiode array structures in one embodiment of the present invention; and

FIG. 12 is a flowchart illustrating the manufacturing process steps of the photodiode array structure in one embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

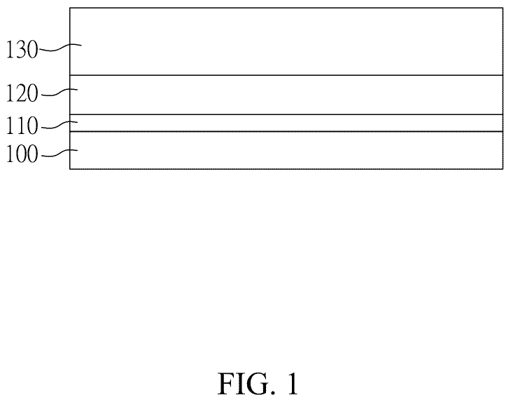

Referring to FIG. 1 to FIG. 9, cross-sectional schematic diagrams illustrate the manufacturing of a photodiode array structure in one embodiment of the present invention. In particular, this photodiode array structure is a compound semiconductor photodiode array structure. In this embodiment, the manufacturing of the photodiode array structure 10 begins with epitaxially growing an ohmic contact epitaxial layer 110 on an epitaxial growth substrate 100, which serves to form an ohmic contact with a metal layer in subsequent metal interconnection processes. Specifically, the epitaxial growth substrate 100 may be, but is not limited to, an indium phosphide (InP) substrate. The ohmic contact epitaxial layer 110 may be, but is not limited to, an indium gallium arsenide (InGaAs) epitaxial layer.

Next, a first conductivity type in-situ doped epitaxial layer 120 and an intrinsic epitaxial layer 130 are sequentially epitaxially grown on the ohmic contact epitaxial layer 110, as shown in FIG. 1. Specifically, the first conductivity type in-situ doped epitaxial layer 120 is an N-type doped epitaxial layer formed by metal-organic chemical vapor deposition (MOCVD), for example, by doping during the epitaxial growth of an indium phosphide (InP) layer with a dopant such as sulfur (S) or silicon (Si) at a doping concentration of approximately 10¹⁷ to 10¹⁹ cm⁻³ to establish an appropriate built-in electric field to drive electron drift. Additionally, the intrinsic epitaxial layer 130 may be an indium gallium arsenide (InGaAs) epitaxial layer disposed on the first conductivity type in-situ doped epitaxial layer 120, with a low doping concentration of approximately 10¹⁴ to 10¹⁵ cm⁻³ to ensure a long carrier drift distance, prevent carrier recombination within the intrinsic epitaxial layer, and effectively separate and drift electron-hole pairs, thereby improving light response efficiency. It should be noted that the first conductivity type in-situ doped epitaxial layer 120 of the present invention features a uniform doping distribution formed through an in-situ doping process. Compared to conventional doping distributions formed by ion implantation and diffusion processes, the uniform doping distribution in the first conductivity type in-situ doped epitaxial layer 120 of the present invention enhances the light response efficiency and gain current of the photodiode.

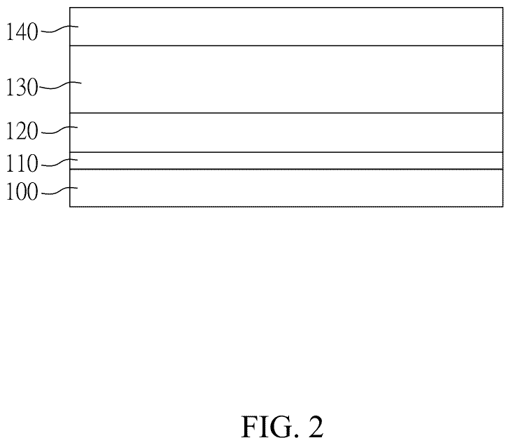

Referring to FIG. 2, a second conductivity type epitaxial layer 140 is then epitaxially grown on the intrinsic epitaxial layer 130. Specifically, this second conductivity type epitaxial layer 140 may be, but is not limited to, a P-type indium phosphide (InP) epitaxial layer. This P-type indium phosphide epitaxial layer may be formed using conventional ion implantation and diffusion processes or, similar to the above, an in-situ doping process with a dopant such as zinc (Zn), magnesium (Mg), or beryllium (Be), with a doping concentration of 10¹⁷ to 10¹⁹ cm⁻³.

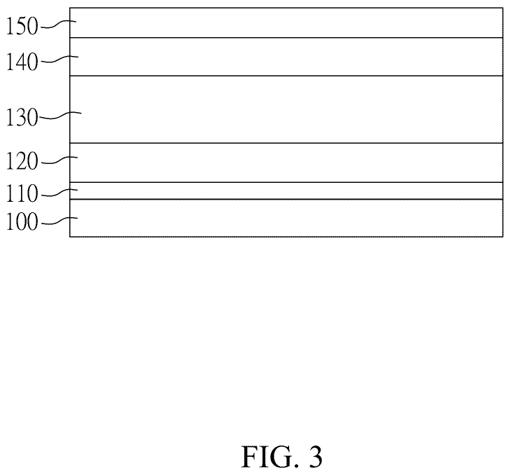

Next, an optical bonding layer 150 is grown on the second conductivity type epitaxial layer 140, as shown in FIG. 3, for subsequent wafer transfer and bonding. In particular, this optical bonding layer 150 may also serve as an optical reflective layer, such as, but not limited to, a distributed Bragg reflector (DBR) layer. This DBR layer is constructed using alternating layers of high and low refractive index materials, such as silicon oxide and titanium oxide, to form a reflective film that strongly reflects light of specific wavelengths due to interference effects at the multilayer interfaces. The reason for using a DBR film as the optical bonding layer 150 in the present invention is to leverage its optical reflective properties to effectively block noise from the bottom of the device and enhance the response capability of the photodiode.

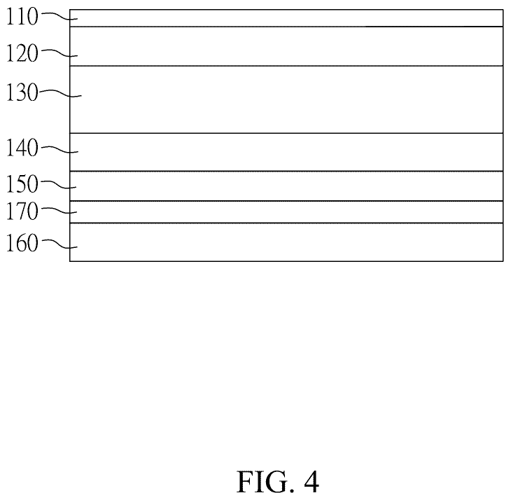

Next, as shown in FIG. 4, a transparent substrate 160, such as, but not limited to, a sapphire substrate, is provided. The transparent substrate 160 has a passivation layer 170, specifically selected from the group consisting of silicon oxide, titanium oxide, and combinations thereof, to facilitate the transfer and bonding of the epitaxial growth substrate 100 and the transparent substrate 160 in conjunction with the optical bonding layer 150. The passivation layer 170 of the transparent substrate 160 is bonded to the optical bonding layer 150 on the epitaxial growth substrate 100. For example, a chemical solution may be used to treat the surfaces of the optical bonding layer 150 and the passivation layer 170 to form dangling bonds, followed by high-temperature and high-pressure application of van der Waals forces to bond the two wafers. After the optical bonding layer 150 and the passivation layer 170 are bonded, the indium phosphide epitaxial growth substrate 100 is removed through selective chemical etching, with the etching stopping at the indium gallium arsenide (InGaAs) ohmic contact epitaxial layer 110.

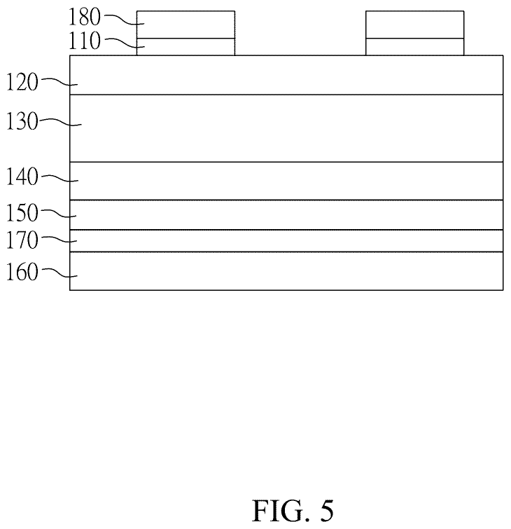

Next, a lift-off deposition process is used to form a first conductivity type metal ring 180 on the ohmic contact epitaxial layer 110. The first conductivity type metal ring 180 is then used as a patterned protective layer to etch away portions of the ohmic contact epitaxial layer 110 exposed outside the first conductivity type metal ring 180 for forming a first conductivity type metal ring 180 and a patterned ohmic contact epitaxial layer 110 on the surface of the first conductivity type in-situ doped epitaxial layer 120, as shown in FIG. 5. Specifically, the first conductivity type metal ring 180 is an N-type metal material, which may be, but is not limited to, chromium (Cr), palladium (Pd), gold (Au), titanium (Ti), aluminum (Al), silver (Ag), or a combination thereof.

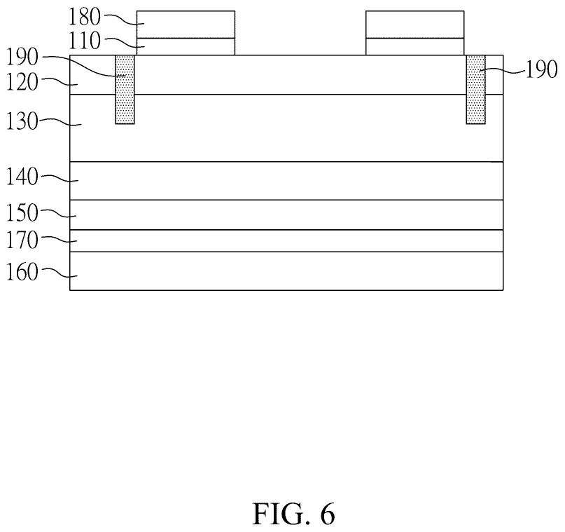

Next, referring to FIG. 6, to address the issue of low signal-to-noise ratio caused by external light interference, the present invention employs a first laser to form a first laser-sintered sidewall 190 at the outer peripheral edge of the photodiode array structure 10 using laser sintering. This sidewall is disposed at the outer peripheral edge of the first conductivity type in-situ doped epitaxial layer 120 to substantially define a light-collecting area and block external light from entering the first conductivity type in-situ doped epitaxial layer 120, as shown in FIG. 6. In particular, the first laser-sintered sidewall 190 is disposed on the inner side of the device sidewall, with the first conductivity type metal ring 180 disposed at the upper inner edge of the first laser-sintered sidewall 190. This sidewall prevents unintended external light from entering the light-collecting area through the device sidewall, avoiding subsequent malfunctions. Specifically, a green laser or ultraviolet (UV) laser may be used to form a laser-sintered sidewall with a length of at least 1 micrometer (μm) at the outer peripheral edge of the first conductivity type in-situ doped epitaxial layer 120 to substantially block external light from entering the light-collecting area. The length of this first laser-sintered sidewall 190 may be adjusted based on the specific requirements of the photodiode array structure. Preferably, the first laser-sintered sidewall 190 may further extend into the intrinsic epitaxial layer to ensure that unintended external light does not enter the light-collecting area through the device sidewall, free of causing erroneous noise, while also enhancing the electrostatic protection capability of the photodiode array structure.

It should be noted that traditional photodiode light-collecting areas are defined by diffusion processes, which result in less uniform doping compared to the in-situ doped epitaxial layers of the present invention. In traditional diffusion-based doping, only the diffused regions form the anode-intrinsic-cathode (PIN) junction structure necessary for generating an internal electric field to produce photocurrent, while non-diffused regions lack an electric field and cannot generate photocurrent. In contrast, the light-collecting area of the photodiode of the present invention uses an in-situ doped epitaxial structure with uniform doping distribution, requiring the first laser-sintered sidewall 190 to effectively isolate the light-collecting and non-light-collecting regions thereof to prevent the non-light-collecting regions from generating an electric field and causing unnecessary noise. In other words, as shown in FIG. 6, the first laser-sintered sidewall 190 in the present invention must extend into the intrinsic epitaxial layer 130 to provide environmental noise suppression.

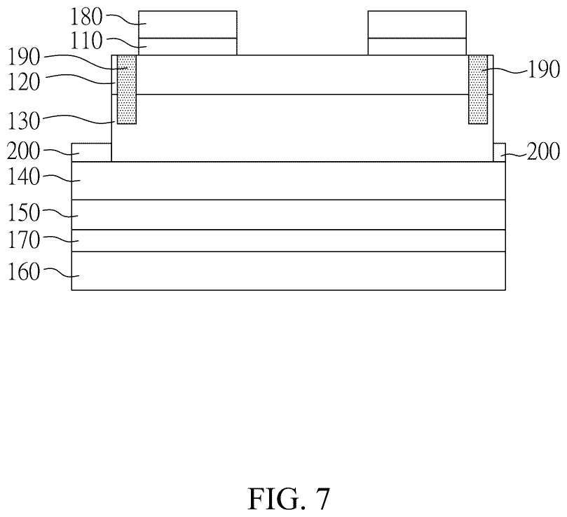

Next, a mesa etching process is performed. Portions of the first conductivity type in-situ doped epitaxial layer 120 and the intrinsic epitaxial layer 130 are removed using dry or wet etching to form a mesa epitaxial layer in a horizontal device structure, as shown in FIG. 7, exposing a portion of the surface of the second conductivity type epitaxial layer 140 for the placement of the second conductivity type metal ring serving as a common electrode. A metal process is then performed to form a second conductivity type metal ring 200 on the exposed surface of the second conductivity type epitaxial layer 140 outside the sidewall of the mesa epitaxial layer, electrically connected to the second conductivity type epitaxial layer 140. Specifically, the second conductivity type metal ring 200 is a P-type metal material, which may be, but is not limited to, platinum (Pt), palladium (Pd), gold (Au), or a combination thereof. It should be noted that, to meet the needs of the subsequent photodiode array structure, the mesa etching process maximizes the area of the mesa epitaxial layer to increase the light-collecting area of the photodiode. For example, the cross-sectional dimensions of the second conductivity type metal rings 200 on the left and right sides of the mesa epitaxial layer may differ. As shown in FIG. 7, the right-side second conductivity type metal ring, used for physical and electrical connection between two adjacent photodiode structures, is minimized in size, while the left-side second conductivity type metal ring, used for external electrical connection, maintains standard dimensions to maximize the light-collecting area of the overall die.

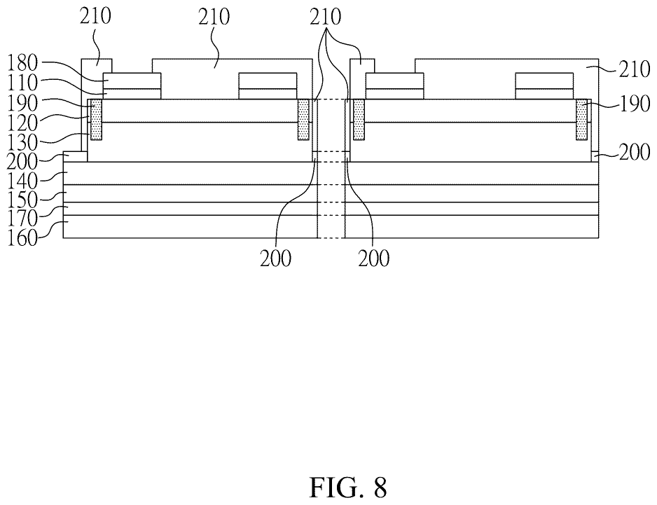

Referring to FIG. 8, the diagram shows two photodiode dies on the left and right sides, each identical to the above disclosure, with the central dashed area indicating a variable number of identical photodiodes based on actual requirements, illustrating one embodiment of the photodiode array structure of the present invention. Based on the foregoing, during the mesa etching process for adjacent dies as shown in FIG. 7, the second conductivity type metal rings 200 on adjacent sides of adjacent dies are physically closely positioned and electrically connected in series to achieve internal metal interconnection in the array structure. Notably, after the wafer bonding process shown in FIG. 4, the first conductivity type in-situ doped epitaxial layer 120, originally positioned above the indium phosphide (InP) epitaxial growth substrate 100 and the ohmic contact epitaxial layer 110 as shown in FIG. 3, is inverted after bonding and substrate removal, transforming the structure from a conventional top-to-bottom PIN structure to a top-to-bottom NIP structure, reversing the polarity of the device electrodes. Consequently, the first conductivity type metal ring 180 electrically connected to the first conductivity type in-situ doped epitaxial layer 120 becomes an N-type electrode, while the second conductivity type metal ring 200 electrically connected to the second conductivity type epitaxial layer 140 becomes a P-type electrode, enabling the second conductivity type metal rings 200 of adjacent dies to be connected in series to form a common anode.

To control the wavelength range of light entering the photodiode, the present invention employs a special optical material to replace conventional protective layers, providing both electrical insulation and filtering functions. As shown in FIG. 8, an optical filtering layer 210 covers the surface and sidewalls of the mesa epitaxial layer, partially covering the first conductivity type metal ring 180 and the second conductivity type metal rings 200 on adjacent sides of two dies, while leaving portions of the first conductivity type metal ring 180 and the second conductivity type metal rings 200 on the outer sides of the dies exposed. Specifically, the optical filtering layer 210 covers the exposed upper surface of the first conductivity type in-situ doped epitaxial layer 120 and the exposed sidewalls of the first conductivity type in-situ doped epitaxial layer 120 and the intrinsic epitaxial layer 130, precisely controlling the entry of external light with specific wavelengths into the mesa epitaxial layer while blocking other wavelengths, thereby eliminating unintended external noise interference.

Specifically, in one embodiment, the optical filtering layer 210 is a multi-channel band-pass filter (MBPF) layer covering the surface and sidewalls of the mesa epitaxial layer. In practical applications, the composition of the MBPF layer can be adjusted based on the desired filtering wavelength band, using dielectric materials such as, but not limited to, silicon oxide (SiOₓ), titanium oxide (TiOₓ), or tantalum oxide (Ta₂O₃). In a preferred embodiment, the optical filtering layer 210 further includes an anti-reflection (AR) layer to enhance the transmission of light in the specific wavelength band and reduce surface reflection loss of the optical filtering layer 210.

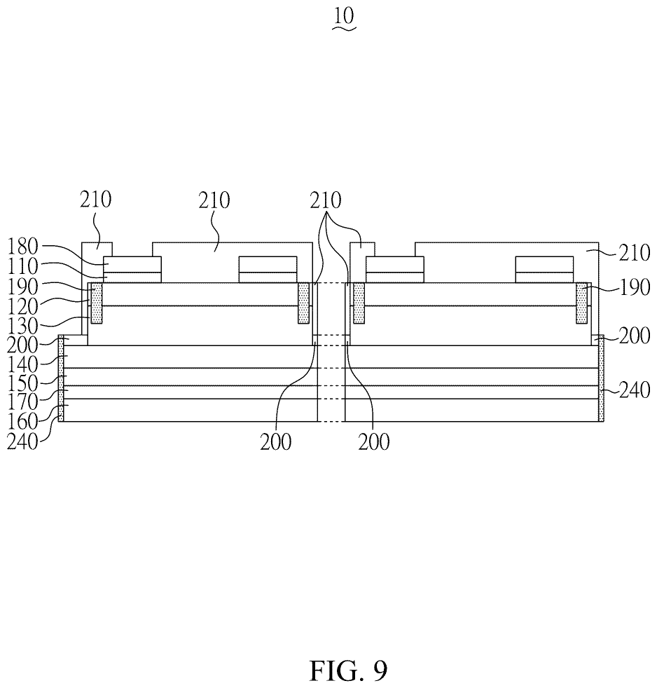

Finally, referring to FIG. 9, the sapphire substrate is diced. In practical applications, the outermost sidewalls of the array structure, comprising multiple photodiodes, are diced according to the design requirements of the array structure, resulting in an array structure containing multiple independently operable and electrically interconnected photodiodes. Specifically, a second laser is used to perform laser cutting on the outermost sidewalls of the array structure, forming a second laser-sintered sidewall 240 on the sidewalls of the transparent substrate 160, passivation layer 170, optical bonding layer 150, second conductivity type epitaxial layer 140, and second conductivity type metal ring 200, thereby forming a photodiode array structure 10. This second laser-sintered sidewall 240 also prevents external light from entering the device through the sidewalls, causing interference. As shown in FIG. 9, each photodiode in the photodiode array structure of the present invention has an independent first conductivity type pad, enabling individual operation of each photodiode. However, to maximize the light-collecting area of the array structure, the second conductivity type metal rings 200 between adjacent dies are electrically connected in series to form a common anode, reducing the number of pads required for external electrode connections and increasing the light-collecting area. In other words, the common electrode design of the present invention allows the photodiode array structure to require only one pad for external electrode connection in one of the photodiode dies, thereby increasing the overall light-collecting area of the array structure and enhancing integration among the dies.

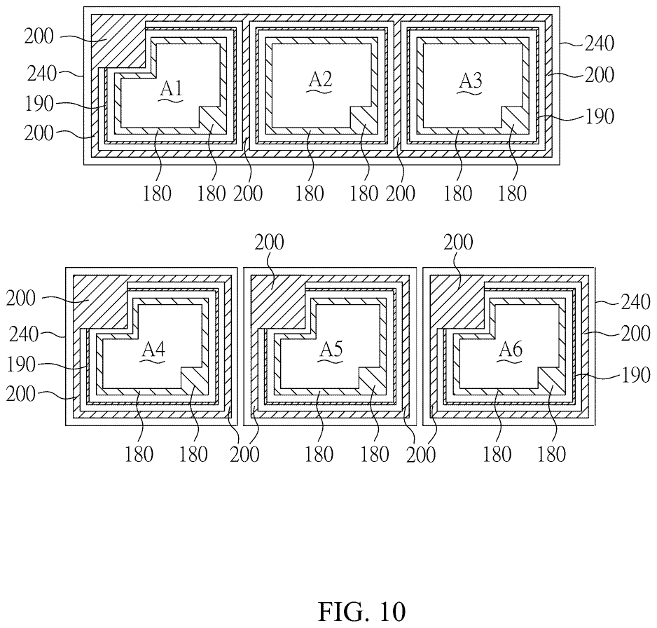

Referring to FIG. 10, a schematic diagram compares the photodiode array structure employing the present invention with one not employing the present invention. The upper half of the figure shows a photodiode array structure employing the present invention, specifically a 1×3 linear array structure comprising three photodiode dies: a first photodiode die A1, a second photodiode die A2, and a third photodiode die A3. Clearly, this photodiode array structure includes three square-shaped first conductivity type metal rings 180 disposed in the first photodiode die A1, second photodiode die A2, and third photodiode die A3, respectively, but only one square-shaped second conductivity type metal ring 200 is disposed in the first photodiode die A1. The second and third photodiode dies A2 and A3 do not have square-shaped second conductivity type metal rings 200; instead, they are connected in series through the second conductivity type metal rings 200 between adjacent dies, achieving a common anode for the three dies while maintaining their individual operation to avoid increased junction capacitance which impacts on switching speed.

In contrast, the lower half of FIG. 10 shows a photodiode array structure not employing the present invention. That is, the structure comprises three photodiode dies—fourth photodiode die A4, fifth photodiode die A5, and sixth photodiode die A6—has features similar to the first photodiode die A1 in the upper half. Each die includes a complete square-shaped first conductivity type metal ring 180 and a square-shaped second conductivity type metal ring 200. Unlike the array structure of the present invention shown in the upper half, the 1×3 array structure does not employ the present invention. Particular, the second conductivity type metal rings 200 between adjacent dies are neither physically nor electrically connected. In practical applications, the fourth, fifth, and sixth photodiode dies A4, A5, and A6 cannot be placed closely together, requiring space for pathways between die bonding positions to prevent damage from compression. Comparing the upper and lower halves of FIG. 10, it is evident that the photodiode array structure of the present invention saves the space typically required for two square-shaped second conductivity type metal rings 200, significantly increasing the light-collecting area while maintaining the advantage of individual die operation. Additionally, due to the shared second conductivity type metal ring 200 forming a common anode, the length of the photodiode array structure employing the present invention is significantly shorter than that of the structure not employing the present invention, enhancing integration and facilitating further miniaturization of packaged chips.

It should be noted that simply increasing the light-collecting area by enlarging a single die, such as combining three smaller dies into one larger die, would increase the light-collecting area but also significantly increase the junction capacitance of the larger die, severely impacting the switching speed of photodiodes in high-frequency applications. In summary, the design of the present invention achieves the advantage of increasing the light-collecting area while maintaining the operational characteristics of individual dies, keeping junction capacitance comparable to that of a single die, meeting the requirements for high-frequency device operation, and improving integration to support the trend toward chip miniaturization.

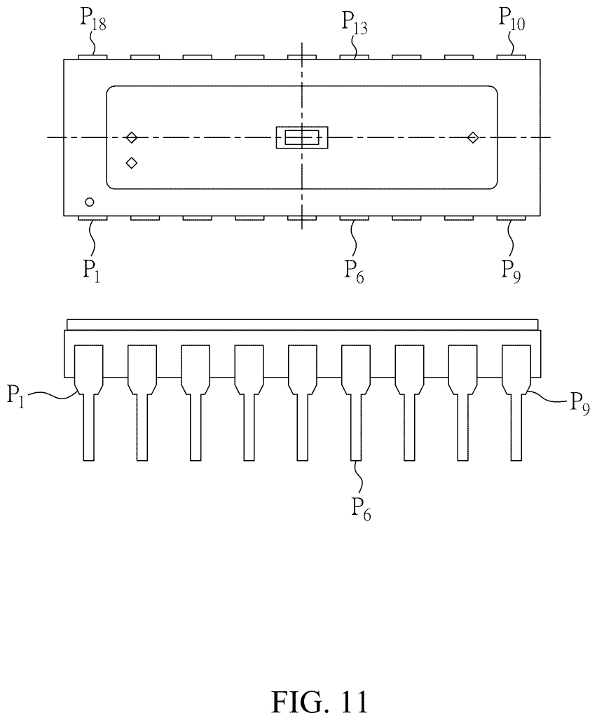

Referring to FIG. 11, a specific embodiment of a packaged chip employing the photodiode array structure of the present invention is shown. The packaged chip includes two array structures of the present invention, arranged integrally to form a linear chip. Each array structure comprises eight photodiode dies arranged in a 1×8 linear matrix, resulting in a total of 16 photodiode dies in the packaged chip. As shown in Table 1 below, the 16 photodiode dies in the packaged chip have 18 pins, with 16 pins serving as cathodes distributed across pins P₁ to P₅, P₇ to P₁₂, and P₁₄ to P₁₈. The 16 photodiode dies share only two common pins as anodes, located at pins P₆ and P₁₃. Clearly, the number of pins in the packaged chip employing the present invention is significantly reduced due to the shared anode configuration, enhancing high integration and miniaturization in chip size.

TABLE 1

| Pin | P₁ | P₂ | P₃ | P₄ | P₅ | P₆ | P₇ | P₈ | P₉ | P₁₀ | P₁₁ | P₁₂ | P₁₃ | P₁₄ | P₁₅ | P₁₆ | P₁₇ | P₁₈ |
|---|---|---|---|---|---|---|---|---|---|---|---|---|---|---|---|---|---|---|
| Function | C | C | C | C | C | A | C | C | C | C | C | C | A | C | C | C | C | C |

“C” standing for cathode
“A” standing for anode

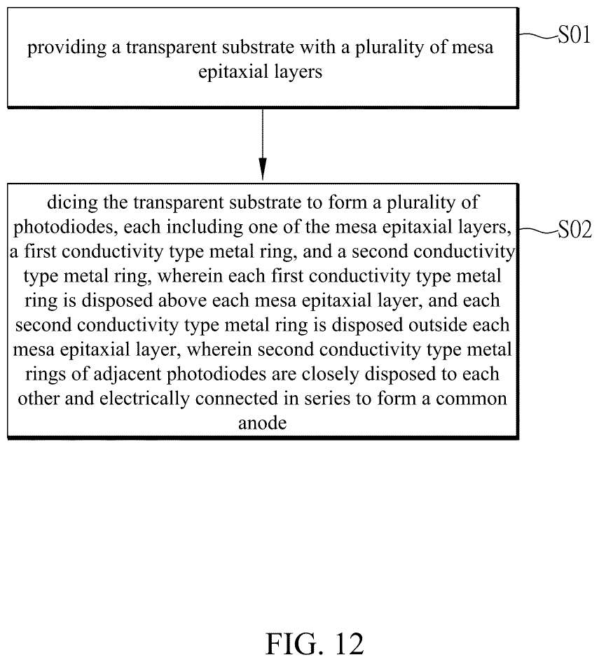

Referring to FIG. 12, a flowchart illustrates the manufacturing process steps of the photodiode array structure of the present invention. In step S01, a transparent substrate with a plurality of mesa epitaxial layers is provided. In step S02, the transparent substrate is diced to form a plurality of photodiodes, each including one of the mesa epitaxial layers, a first conductivity type metal ring, and a second conductivity type metal ring, wherein each first conductivity type metal ring is disposed above each mesa epitaxial layer, and each second conductivity type metal ring is disposed outside each mesa epitaxial layer. The second conductivity type metal rings of adjacent photodiodes are closely disposed to each other and electrically connected in series to form a common anode. Detailed descriptions of related components can refer to the above content and are not repeated here.

In summary, the photodiode array structure 10 of the present invention offers the following advantages. First, by utilizing wafer transfer and bonding technology, the photodiode device body is transferred to a high-strength sapphire transparent substrate, addressing the fragility of conventional indium phosphide substrates used in SWIR photodiodes, improving structural integrity, increasing manufacturing yield, and reducing production costs to meet cost-effective production requirements. Second, the photodiode array structure of the present invention incorporates multiple designs to block external noise interference for improving the device's signal-to-noise ratio and enhancing light response efficiency and photocurrent gain. For example, an optical bonding layer with a reflective mirror structure is disposed above the transparent substrate at the bottom of the device to reflect external light from the bottom for preventing noise interference. Regarding the device sidewalls, two laser-sintered sidewalls are provided: a first laser-sintered sidewall to prevent noise from entering the light-collecting area and a second laser-sintered sidewall at the outermost edge, both effectively blocking noise from the sidewalls. At the device top, a multi-channel band-pass filter layer allows only light of specific wavelength bands to pass while blocking others. Additionally, an anti-reflection layer enhances the transmission of specific wavelength bands and reduces surface reflection loss of the optical filtering layer. Thus, the photodiode array structure of the present invention provides comprehensive noise suppression, significantly improving the signal-to-noise ratio and photocurrent gain. Third, the photodiode array structure of the present invention features a shared electrode design between adjacent dies, enhancing the integration of packaged chips. Forth, the shared electrode design increases the light-collecting area for improving light response efficiency while maintaining single-die junction capacitance characteristics, meeting the requirements for high-frequency device switching speeds and supporting chip miniaturization trends.

The above embodiments are provided to illustrate the implementations of the present invention and to explain its technical features, and are not intended to limit the scope of the present invention. Any modifications or equivalent arrangements that can be easily accomplished by those skilled in the art fall within the scope of the present invention, and the scope of the present invention should be defined by the claims.

What is claimed is:

1. A photodiode array structure, comprising:
a plurality of photodiodes, wherein each of the photodiodes comprises:
a transparent substrate;
a mesa epitaxial layer including an intrinsic epitaxial layer, a first conductivity type in-situ doped epitaxial layer, and a laser-sintered sidewall, wherein the first conductivity type in-situ doped epitaxial layer is disposed on the intrinsic epitaxial layer, and the laser-sintered sidewall is disposed at an outer peripheral edge of the first conductivity type in-situ doped epitaxial layer to substantially define a light-collecting area for each of the photodiodes;
a second conductivity type epitaxial layer disposed on the transparent substrate, with the mesa epitaxial layer disposed on the second conductivity type epitaxial layer;
a first conductivity type metal ring disposed on the surface of the first conductivity type in-situ doped epitaxial layer inside the laser-sintered sidewall; and
a second conductivity type metal ring disposed adjacent to the sidewall of the mesa epitaxial layer and electrically connected to the second conductivity type epitaxial layer,
wherein the second conductivity type metal rings of the adjacent photodiodes are closely disposed to each other and electrically connected in series to form a common anode.

2. The photodiode array structure of claim 1, wherein each of the first conductivity type in-situ doped epitaxial layers is an N-type in-situ doped indium phosphide (InP) epitaxial layer with a dopant selected from sulfur (S) and silicon (Si) with a doping concentration of 10¹⁷ to 10¹⁹ cm⁻³.

3. The photodiode array structure of claim 1, wherein each of the photodiodes further comprises an optical bonding layer interposed between each of the transparent substrates and each of the second conductivity type epitaxial layers to block external light from entering the second conductivity type epitaxial layers through the transparent substrates.

4. The photodiode array structure of claim 3, wherein each of the optical bonding layers is a distributed Bragg reflector (DBR) layer.

5. The photodiode array structure of claim 1, wherein each of the photodiodes further comprises an optical filtering layer, each of the optical filtering layers is a multi-channel band-pass filter (MBPF) layer covering the surface and sidewalls of each of the mesa epitaxial layers for allowing light with a specific wavelength band from external light to pass while blocking other wavelengths therefrom from entering the light-collecting areas.

6. The photodiode array structure of claim 5, wherein each of the optical filtering layers further comprises an anti-reflection (AR) layer to reduce surface reflection loss of each of the optical filtering layers.

7. A photodiode array structure, comprising:
a plurality of photodiodes, wherein each of the photodiodes comprises a light-collecting area, a first conductivity type metal ring, and a second conductivity type metal ring, wherein each of the first conductivity type metal rings is disposed above each of the light-collecting areas, and each of the second conductivity type metal rings is disposed outside each of the light-collecting areas,
wherein the second conductivity type metal rings of the adjacent photodiodes are closely disposed to each other and electrically connected in series to form a common anode.

8. The photodiode array structure of claim 7, wherein each of the photodiodes further comprises a mesa epitaxial layer having an intrinsic epitaxial layer, a first conductivity type in-situ doped epitaxial layer, and a laser-sintered sidewall, wherein each of the first conductivity type in-situ doped epitaxial layers is disposed on each of the intrinsic epitaxial layers, and each of the laser-sintered sidewalls is disposed at an outer peripheral edge of each of the first conductivity type in-situ doped epitaxial layers to substantially define each of the light-collecting areas of each of the photodiodes.

9. The photodiode array structure of claim 8, wherein each of the photodiodes further comprises a second conductivity type epitaxial layer, with each of the mesa epitaxial layers disposed on each of the second conductivity type epitaxial layers, each of the first conductivity type metal rings electrically connected to each of the first conductivity type in-situ doped epitaxial layers, and each of the second conductivity type metal rings electrically connected to each of the second conductivity type epitaxial layers.

10. The photodiode array structure of claim 9, wherein each of the photodiodes further comprises an optical bonding layer and a transparent substrate, with each of the optical bonding layers interposed between each of the transparent substrates and each of the second conductivity type epitaxial layers to block external light from entering the second conductivity type epitaxial layers through the transparent substrates.

11. The photodiode array structure of claim 10, wherein each of the optical bonding layers is a distributed Bragg reflector (DBR) layer.

12. The photodiode array structure of claim 8, wherein each of the photodiodes further comprises an optical filtering layer, each of the optical filtering layers is a multi-channel band-pass filter (MBPF) layer covering the surface and sidewalls of each the mesa epitaxial layers for allowing light of a specific wavelength band from external light to pass while blocking other wavelengths therefrom from entering the light-collecting areas.

13. The photodiode array structure of claim 12, wherein each of the optical filtering layers further comprises an anti-reflection (AR) layer to reduce surface reflection loss of each of the optical filtering layers.

14. A method for manufacturing a photodiode array structure, comprising:
providing a transparent substrate having a plurality of mesa epitaxial layers thereon; and
dicing the transparent substrate to form a plurality of photodiodes, each of the photodiodes including one of the mesa epitaxial layers, a first conductivity type metal ring, and a second conductivity type metal ring, wherein each of the first conductivity type metal rings is disposed above each of the mesa epitaxial layers, and each of the second conductivity type metal rings is disposed outside each of the mesa epitaxial layers,
wherein the second conductivity type metal rings of the adjacent photodiodes are closely disposed to each other and electrically connected in series to form a common anode.

15. The method of claim 14, wherein each of the mesa epitaxial layers includes an intrinsic epitaxial layer, a first conductivity type in-situ doped epitaxial layer, and a laser-sintered sidewall, wherein each of the first conductivity type in-situ doped epitaxial layers is disposed on each of the intrinsic epitaxial layers, and each of the laser-sintered sidewalls is disposed at an outer peripheral edge of each of the first conductivity type in-situ doped epitaxial layers to substantially define a light-collecting area for each of the photodiodes.

16. The method of claim 15, wherein each photodiode further includes a second conductivity type epitaxial layer, with each of the mesa epitaxial layers disposed on each of the second conductivity type epitaxial layers, each of the first conductivity type metal rings electrically connected to each of the first conductivity type in-situ doped epitaxial layers, and each of the second conductivity type metal rings electrically connected to each of the second conductivity type epitaxial layers.

17. The method of claim 16, wherein each of the photodiodes further includes an optical bonding layer and a transparent substrate, with each of the optical bonding layers interposed between each of the transparent substrates and each of the second conductivity type epitaxial layers to block external light from entering the second conductivity type epitaxial layers through the transparent substrates.

18. The method of claim 15, wherein each of the photodiodes further includes an optical filtering layer, each of the optical filtering layers is a multi-channel band-pass filter (MBPF) layer covering the surface and sidewalls of each of the mesa epitaxial layers for allowing light of a specific wavelength band from external light to pass while blocking other wavelengths therefrom from entering the light-collecting areas.

19. The method of claim 18, wherein each of the optical filtering layers further includes an anti-reflection (AR) layer to reduce surface reflection loss of each of the optical filtering layers.
